(19) United States
(12) Patent Application Publication
(10) Pub. No.: US 2017/0146831 A1
(43) Pub. Date: May 25, 2017

(54) Mask Device for Optical Alignment and Equipment Thereof

(71) Applicant: Shenzhen China Star Optoelectronics Technology Co., Ltd., Shenzhen, Guangdong (CN)

(72) Inventors: Bing HAN, Shenzhen, Guangdong (CN); Ming-hung SHIH, Shenzhen, Guangdong (CN); Meng LI, Shenzhen, Guangdong (CN)

(73) Assignee: Shenzhen China Star Optoelectronics Technology Co., Ltd., Shenzhen, Guangdong (CN)

(21) Appl. No.: 14/765,800

(22) PCT Filed: May 25, 2015
(86) PCT No.: PCT/CN2015/079703

§ 371 Date: Aug. 4, 2015

(30) Foreign Application Priority Data
Apr. 27, 2015 (CN) 201510206165.9

(51) Int. Cl. G02F 1/13; G03F 7/20; G02F 1/1337

(52) U.S. Cl. CPC G02F 1/1303; G02F 1/133788; G03F 7/2045

(57) ABSTRACT

A mask device for optical alignment and equipment thereof are disclosed. The mask device comprises a first mask having a first overlapping region and a first non-overlapping region and a second mask having a second overlapping region and a second non-overlapping region. The first and second mask overlap with each other. The first overlapping and non-overlapping regions, the second overlapping and non-overlapping regions comprise openings respectively. The height of the openings of the first and the second overlapping region are arranged to vary according the trigonometric square such that the height of the openings at the same position that the overlapping regions overlap with each other is the same as that the openings of the first or the second non-overlapping regions. Compared with the current technology, the disclosure may eliminate the defects of the striped mura in the liquid crystal display to increase the display quality of the products.

### BACKGROUND

Technical Field

The disclosure is related to the technology field of the liquid crystal display, and more particular to a mask device for optical alignment and equipment thereof.

Related Art

By applying an electric field to the field generating electrode of the upper and the lower display panel, the liquid crystal of the liquid crystal layer in the liquid crystal device deflects under the influence of the electric field. Therefore, the image display can be achieved by controlling the polarized light incident to the liquid crystal layer. Currently, vertical alignment (VA, vertical alignment) mode liquid crystal display has been widely studied and applied because of its high contrast and wide viewing angle standard.

In the production process of the liquid crystal display, the friction alignment and the optical alignment are often used. The friction alignment method would produce static electricity and particulate pollution. The optical alignment method is a non-contact alignment technique, utilizing linearly polarized light irradiating on the sensitive polymer alignment film such that the liquid crystal of the liquid crystal layer and the display panel re formed with an inclination angle.

The common used optical alignment method is UV²A (ultra violet vertical alignment) technique. The principle is the use of UV (ultra violet) light having a certain angle to irradiate on the optical alignment film of the array substrate or the color filter substrate through a mask, so that the optical alignment film layer may have alignment reaction such that the liquid crystal molecules are in a certain angle (1-5°) arrangement with the normal line of the array substrate or color filter substrate. The mask size used in the optical alignment is usually smaller than the size of the liquid crystal display on the market, and therefore it needs to use multiple masks simultaneously. The overlapping areas are irradiated twice.

Refer to FIG. 1a for the schematic view of the openings of the overlapping regions of the two masks for optical alignment in the prior art. As shown in FIG. 1, the mask 110 and the mask 120 have overlapping regions. The overlapping region of the mask is denoted as 1101, and the non-overlapping region is denoted as 1102, on which a plurality of openings 1103 and 1104 are formed. The openings are the exposure regions for light transmission. The overlapping region of the mask 120 is denoted as 1201, and the non-overlapping region is denoted as 1202, on which a plurality of openings 1203 and 1204 are also formed. Refer to FIG. 1a for the schematic view showing the variation of the openings (or corresponding exposure amount) of the overlapping regions of the two masks in FIG. 1a. Specifically, the mask 120 is taken as an example. The variation of the opening 1203 of the overlapping region 1201 is denoted as the curve 12011, which presents linear variation. The variation of the openings 1204 of the non-overlapping region 1202 is denoted as the curve (or straight line) 12021, which is a linear constant. Similarity, the variation of the opening 1103 of the overlapping region 1101 of the mask 1101 is denoted as the curve 11011, which presents linear variation. The variation of the openings 1104 of the non-overlapping region 1102 is denoted as the curve (or straight line) 11021, which is also a linear constant. In the overlapping region, the curve 11011 and the curve 12011 satisfy that the overlapping value is the same as the value of the curve 11021 or 12021 of the openings of the non-overlapping regions of the mask 110 or 120. That is the overlapping exposure amount of the opening 1101 and 1201 of the overlapping regions of the mask 110 and the mask 120 is the same as the exposure amount of the opening 1102 or 1202 of the non-overlapping regions of the mask 110 or the mask 120.

However, the openings of the overlapping regions of the masks are linear variation. That is the corresponding exposure amount is also linear variation such that the defects of stripped mura occur in the display panel to impede the quality of the product.

### SUMMARY

The technique problem solved by the disclosure is to provide a mask device for optical alignment and equipment thereof to achieve the curved (smooth) variation for the exposure amount of the openings of the overlapping regions of the two masks, to further eliminate the defects of the striped mura in the liquid crystal display and increase the display quality of the products.

To solve the above technical problem, one technical solution adopted by the disclosure is to provide a device comprising:

a first mask and a second mask;

the first mask comprises a first overlapping region and a first non-overlapping region;

the second mask comprises a second overlapping region and a second non-overlapping region;

the first overlapping region and the second overlapping region overlap with each other;

the first overlapping region comprises a plurality of transmission openings arranged in a first direction;

the first non-overlapping region comprises a plurality of transmission openings arranged in the first direction;

the second overlapping region comprising a plurality of transmission openings arranged in the first direction;

the second non-overlapping region comprises a plurality of transmission openings arranged in the first direction;

the openings of the first non-overlapping region and the openings of the second non-overlapping region are the same;

the height Y1 of the openings of the first overlapping region satisfies Y1=H sin²(πX/2L);

the height Y2 of the openings of the second overlapping region satisfies Y2=H cos²(πX/2L);

wherein H is the height of the openings of the first non-overlapping region and the height of the openings of the second non-overlapping region; X=L−M; L is the length of the first overlapping region and the length of the second overlapping region; M is the distance between the first overlapping region and the second non-overlapping region or the distance between the second overlapping region and the second non-overlapping region;

the openings of the first non-overlapping region and the openings of the second non-overlapping region are a first rectangular;

the width direction of the first rectangular is the same as the first direction;

the openings of the first overlapping region and the openings of the second overlapping region are a plurality of third rectangular; the size of the third rectangles in the first direction is the same as or different from the width of the first rectangular;

the openings of the first overlapping region and the openings of the second overlapping region are arranged symmetrically or asymmetrically.

In one embodiment, the openings of the first overlapping region and the openings of the second overlapping region are obtained by mosaic algorithm.

To solve the above technical problem, another technical solution adopted by the disclosure is to provide a device comprising:

a first mask and a second mask;

the first mask comprises a first overlapping region and a first non-overlapping region;

the second mask comprises a second overlapping region and a second non-overlapping region;

the first overlapping region and the second overlapping region overlap with each other;

the first overlapping region comprises a plurality of transmission openings arranged in a first direction;

the first non-overlapping region comprises a plurality of transmission openings arranged in the first direction;

the second overlapping region comprising a plurality of transmission openings arranged in the first direction;

the second non-overlapping region comprises a plurality of transmission openings arranged in the first direction;

the openings of the first non-overlapping region and the openings of the second non-overlapping region are the same;

the height Y1 of the openings of the first overlapping region satisfies Y1=H sin²(πX/2L);

the height Y2 of the openings of the second overlapping region satisfies Y2=H cos²(πX/2L);

wherein H is the height of the openings of the first non-overlapping region and the height of the openings of the second non-overlapping region; X=L−M; L is the length of the first overlapping region and the length of the second overlapping region; M is the distance between the first overlapping region and the second non-overlapping region or the distance between the second overlapping region and the second non-overlapping region.

In one embodiment, the openings of the first non-overlapping region and the openings of the second non-overlapping are a first rectangular; the width direction of the first rectangular is the same as the first direction; the openings of the first overlapping region and the openings of the second overlapping region are a second rectangle; the size of the second rectangular in the first direction is the same as the width of the first rectangular.

In one embodiment, the openings of the first non-overlapping region and the openings of the second non-overlapping region are a first rectangular; the width direction of the first rectangular is the same as the first direction; the openings of the first overlapping region and the openings of the second overlapping region are a plurality of third rectangular; the size of the third rectangular in the first direction is the same as or different from the width of the first rectangular.

In one embodiment, the openings of the first overlapping region and the openings of the second overlapping region are obtained by mosaic algorithm.

In one embodiment, the openings of the first overlapping region and the openings of the second overlapping region overlap with each other.

In one embodiment, the openings of the first overlapping region and the openings of the second overlapping region do not overlap with each other.

In one embodiment, the openings of the first overlapping region and the openings of the second overlapping region are arranged symmetrically or asymmetrically.

To solve the above technical problem, another technical solution adopted by the disclosure is to provide an equipment comprising:

the device of another technical solution mentioned above, a first light source and a second light source;

the first light source provides light for the openings of the first mask;

the second light source provides light for the openings of the second mask.

The advantageous effect of the disclosure is that the device and the equipment of the disclosure comprises a first mask and a second mask partially overlapping with each other such that the first mask comprises a first overlapping region and a first non-overlapping region and the second mask comprises a second overlapping region and a second non-overlapping region, and the first overlapping region and the second overlapping region overlap with each other. In the meanwhile, the first overlapping region comprises a plurality of transmission openings arranged in a first direction; the first non-overlapping region comprises a plurality of transmission openings arranged in the first direction; the second overlapping region comprising a plurality of transmission openings arranged in the first direction; the second non-overlapping region comprises a plurality of transmission openings arranged in the first direction. Specifically, the openings of the first non-overlapping region and the openings of the second non-overlapping region are the same; the height Y1 of the openings of the first overlapping region satisfies Y1=H sin²(πX/2L); the height Y2 of the openings of the second overlapping region satisfies Y2=H cos²(πX/2L); wherein H is the height of the openings of the first non-overlapping region and the height of the openings of the second non-overlapping region; X=L−M; L is the length of the first overlapping region and the length of the second overlapping region; M is the distance between the first overlapping region and the second non-overlapping region or the distance between the second overlapping region and the second non-overlapping region. Compared with the current technology that the openings having linear variation in the overlapping regions of the plurality of masks for optical alignment, the disclosure configures the openings in the overlapping regions of the two masks to satisfy the curve variation of the trigonometric square such that the exposure amount of the openings changes smoother. In the overlapping regions, it satisfies H sin²(πX/2L)+H cos²(πX/2L)=H at the same position. That is the exposure amount of the openings of the overlapping regions and the exposure amount of the openings of the non-overlapping regions is the same after the two masks overlap with each other such that the display effects are uniform in the liquid crystal display device. In the meanwhile, the openings of curved variation may eliminate the defects of the stripped mura in the liquid crystal display device to increase the display quality of the products.

### BRIEF DESCRIPTION OF THE DRAWINGS

The above and other exemplary aspects, features and advantages of certain exemplary embodiments of the present disclosure will be more apparent from the following description taken in conjunction with the accompanying drawings, in which:

FIG. 1a is the schematic view of the openings of the overlapping regions of the two masks for optical alignment in the prior art;

FIG. 1b is the schematic view showing the variation of the openings (or corresponding exposure amount) of the overlapping regions of the two masks in FIG. 1a;

FIG. 2a is the schematic view of the first embodiment of the mask device for optical alignment according to the disclosure;

FIG. 2b is the schematic view showing the height variation of the openings of the overlapping regions of the two masks in FIG. 2a;

FIG. 2c is the schematic view showing the asymmetrical arrangement of the openings of the overlapping regions of the two masks in FIG. 2a;

FIG. 2d is the schematic view showing that the openings of the overlapping regions of the two masks in FIG. 2a overlap with each other;

FIG. 2e is the schematic view showing that the openings of the overlapping regions of the two masks in FIG. 2a do not overlap with each other;

FIG. 3a is the schematic view of the second embodiment of the mask device for optical alignment according to the disclosure;

FIG. 3b is one schematic view showing that the openings of the overlapping regions of the two masks in FIG. 3a comprise a plurality of third rectangles;

FIG. 3c is another schematic view showing that the openings of the overlapping regions of the two masks in FIG. 3a comprise a plurality of third rectangles; and

FIG. 4 is the schematic view of the third embodiment of the exposure equipment for optical alignment according to the disclosure.

### DETAILED DESCRIPTION

The description and explanation are given in more details in the following with reference to the accompanying drawings.

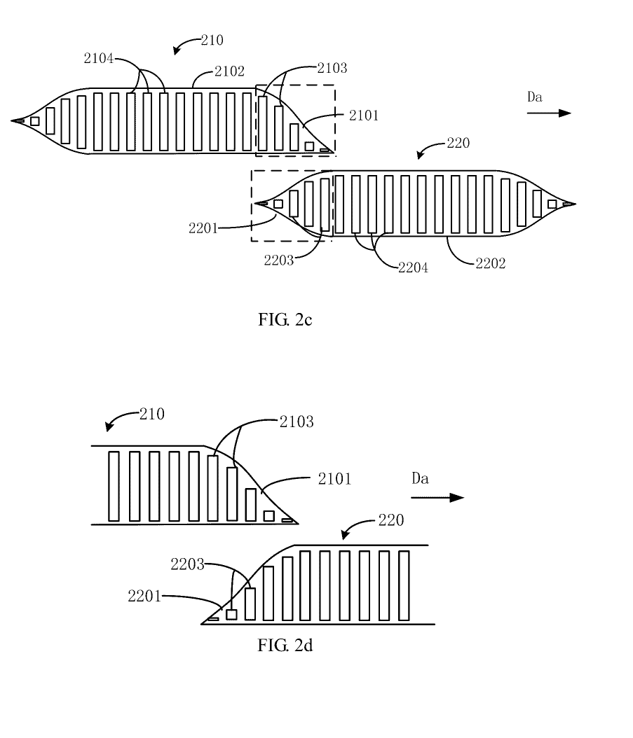

Refer to FIG. 2a and FIG. 2b. FIG. 2a is the schematic view of the first embodiment of the mask device for optical alignment according to the disclosure. FIG. 2b is the schematic view showing the height variation of the openings of the overlapping regions of the two masks in FIG. 2a.

The mask device 20 comprises:

a first mask 210 and a second mask 220;

the first mask 210 comprises a first overlapping region 2101 and a first non-overlapping region 2102;

the second mask 220 comprises a second overlapping region 2201 and a second non-overlapping region 2202;

the first overlapping region 2101 and the second overlapping region 2201 overlap with each other;

the first overlapping region 2101 comprises a plurality of transmission openings 2103 arranged in a first direction Da;

the first non-overlapping region 2102 comprises a plurality of transmission openings 2104 arranged in the first direction Da;

the second overlapping region 2201 comprising a plurality of transmission openings 2203 arranged in the first direction Da;

the second non-overlapping region 2201 comprises a plurality of transmission openings 2204 arranged in the first direction Da;

the openings 2104 of the first non-overlapping region 2102 and the openings 2204 of the second non-overlapping region 2202 are the same;

the height Y1 of the openings 2103 of the first overlapping region 2101 satisfies Y1=H sin²(πkX/2L);

the height Y2 of the openings 2203 of the second overlapping region 2201 satisfies Y2=H cos²(πX/2L);

wherein H is the height of the openings 2104 of the first non-overlapping region 2102 and the height of the openings 2204 of the second non-overlapping region 2202; X=L−M; L is the length of the first overlapping region 2101 and the length of the second overlapping region 2201; M is the distance between the first overlapping region 2101 and the second non-overlapping region 2202 or the distance between the second overlapping region 2201 and the second non-overlapping region 2202;

wherein the openings 2104 and the openings 2204 are the same, indicating the openings have the same shape and the same size.

It can be understood that if the first mask 210 exchanges places with the second mask 220 (ref to FIG. 2a and FIG. 2b), M is the distance between the first overlapping region 2101 and the first non-overlapping region 2102 or the distance between the second overlapping region 2201 and the first non-overlapping region 2102.

In other embodiment, the height Y1 of the openings 2103 of the first overlapping region 2101 may alternatively satisfy Y1=H cos²(πX/2L). Similarity, the height Y2 of the openings 2203 of the second overlapping region 2201 alternatively satisfy Y2=H sin²(πX/2L).

In the specific embodiment, the height H of the openings of the non-overlapping region and the length L of the overlapping region may be design according to the size of the liquid display device. That is the height H of the openings of the non-overlapping region and the length L of the overlapping region are known or present data. Furthermore, the openings 2103 of the overlapping region 2101 and the openings 2203 of the overlapping region 2201 of the two masks are in line with the curve variation of the trigonometric square such that the exposure amount of the openings changes more smoother. Thus the defects of the striped mura in the liquid crystal display may be eliminated to increase the display quality of the products.

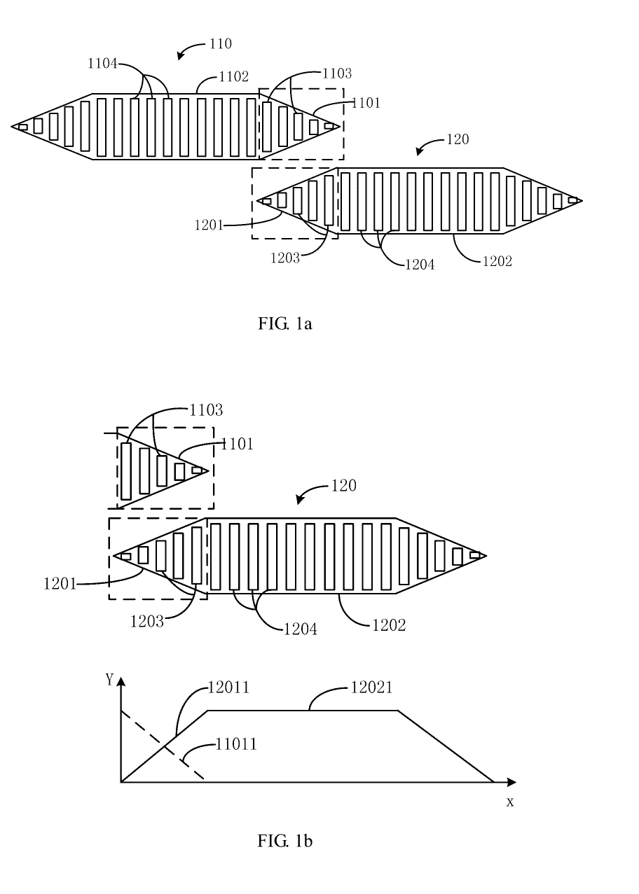

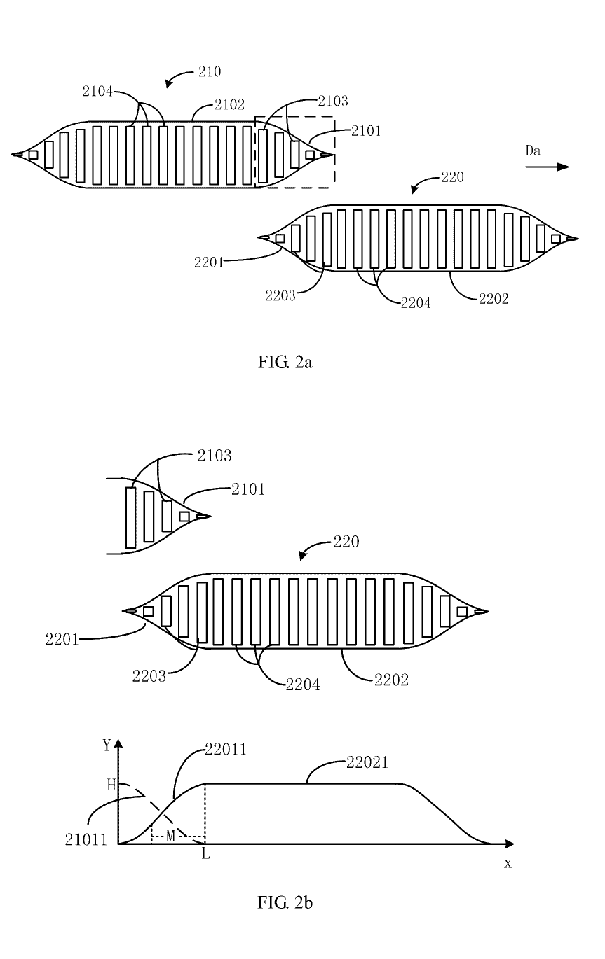

Refer to FIG. 2b continuously. Specifically, the mask 220 is taken for example. The curve 22011 is denoted for the variation of the openings 2203 of the overlapping region 2201, whose trigonometric square changes as sin²(πX/2L). The curve (or straight line) 22021 is denoted for the variation of the openings 2204 of the non-overlapping region 2202, which is a linear constant H. Similarly, the curve 21011 is denoted for the variation of the openings 2103 of the overlapping region 2101, whose trigonometric square changes as cos²(πX/2L). The curve (not shown in FIG. 1b) 21021 is denoted for the variation of the openings 2104 of the non-overlapping region 2102, which is a linear constant H.

The height Y1 of the openings 2103 of the first overlapping region 2102 satisfies Y1=H sin²(πX/2L). The height Y2 of the openings 2203 of the second overlapping region 2201 satisfies Y2=H cos²(πX/2L). When the first mask 210 and the second mask 220 overlap with each other, for the openings at the overlapping region, the height of the openings satisfy Y1+Y2=H at the same position (the same X) after overlapping. That is having the same height as the openings of the non-overlapping region. Thus the existing manufacture conditions for the mask exposure may be well matched.

Specifically, the openings 2104 of the first non-overlapping region 2102 and the openings 2204 of the second non-overlapping region 2201 are first rectangle.

The width direction of the first rectangular is the same as the first direction Da.

The openings 2103 of the first overlapping region 2101 and the openings 2203 of the second overlapping region 2201 are second rectangle; the size of the second rectangular in the first direction Da is the same as the width of the first rectangular. The effective exposure area and the size of the openings 2103 of the first mask 210 and the openings 2203 of the second mask 220 that overlap with each other are the same as the exposure area and the size of the openings 2104 of the non-overlapping region 2102 or the openings 2204 of the non-overlapping region 2203 such that the exposure amount at the overlapping openings of the first mask 210 and the second mask 220 is the same as the exposure amount of the openings of the non-overlapping regions.

In FIG. 2a, the openings 2103 of the first overlapping region 2101 and the openings 2203 of the second overlapping region 2201 are arranged symmetrically. Alternatively, the openings may be arranged asymmetrically.

Refer to FIG. 2c. for the schematic view showing the asymmetrical arrangement of the openings of the overlapping regions of the two masks in FIG. 2a. As shown in FIG. 2c, the openings 2103 of the first overlapping region 2101 and the openings 2104 of the first non-overlapping region 2102 have the same horizontal position of the bottom edge. The openings 2203 of the second overlapping region 2201 are arranged self symmetrically with respect to the horizontal central line of the second mask 220.

Further, alternatively, at least one of the openings 2103 of the first overlapping region 2101 and the openings 2104 of the first non-overlapping region 2102 have the same horizontal position of the top edge. At least one of the openings 2203 of second overlapping region 2201 and the openings 2204 of the second non-overlapping region 2202 have the same horizontal position of the bottom edge or the same horizontal position of the top edge. Thus such configuration makes the openings 2103 of the first overlapping region 2101 and the openings 2104 of the second non-overlapping region 2102 arranged symmetrically or asymmetrically.

Refer to FIG. 2d for the schematic view showing that the openings of the overlapping regions of the two masks in FIG. 2a overlap with each other. The openings 2103 of the first overlapping region 2101 and the openings 2104 of the first non-overlapping 2102 have the same horizontal position of the bottom edge, and the openings 2203 of the second overlapping 2201 and the openings 2204 of the second non-overlapping 2202 also have the same horizontal position of the bottom edge. Therefore, under the situation that the openings 2104 of the first non-overlapping 2102 and the openings 2204 of the second non-overlapping 2202 are the same, the openings 2103 of the first overlapping region 2101 and the openings 2203 of the second overlapping region 2201 overlap with each other when the first mask 210 overlaps with the second mask 220.

As shown in FIG. 2a, the openings of the overlapping regions of the first mask 210 and the second mask 220 are arranged to overlap with each other. As shown in FIG. 2c, the openings of the overlapping regions of the first mask 210 and the second mask 220 are arranged to overlap with each other.

Refer to FIG. 2e for the schematic view showing that the openings of the overlapping regions of the two masks in FIG. 2a do not overlap with each other. As shown in FIG. 2e, the openings 2103 of the first overlapping region 2101 and the openings 2104 of the first non-overlapping 2102 have the same horizontal position of the bottom edge. The openings 2203 of the second overlapping region 2201 and the openings 2204 of the second non-overlapping regions 2202 have the same horizontal position of the top edge. Therefore, under the situation that the openings 2104 of the first non-overlapping 2102 and the openings 2204 of the second non-overlapping 2202 are the same, the openings 2103 of the first overlapping region 2101 and the openings 2203 of the second overlapping region 2201 do not overlap with each other when the first mask 210 overlaps with the second mask 220.

Distinguishing from the current technology, the embodiment configures the openings in the overlapping regions of the two masks to satisfy the curve variation of the trigonometric square such that the exposure amount of the openings changes smoother. In the overlapping regions, it satisfies H sin²(πX/2L)+H cos²(πX/2L)=H at the same position. That is the exposure amount of the openings of the overlapping regions and the exposure amount of the openings of the non-overlapping regions is the same after the two masks overlap with each other such that the display effects are uniform in the liquid crystal display device. In the meanwhile, the openings of curved variation may eliminate the defects of the stripped mura in the liquid crystal display device to increase the display quality of the products.

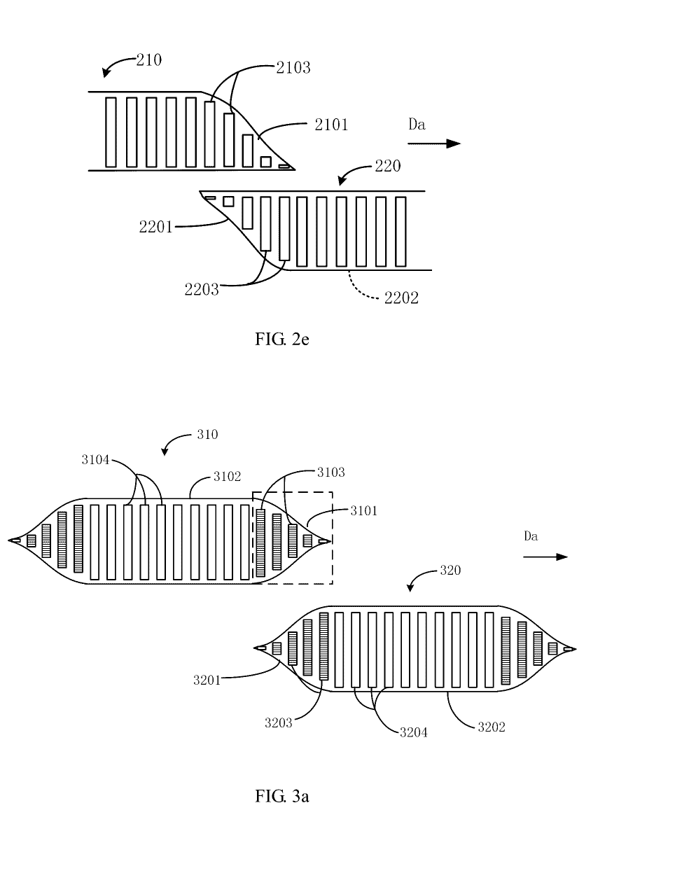

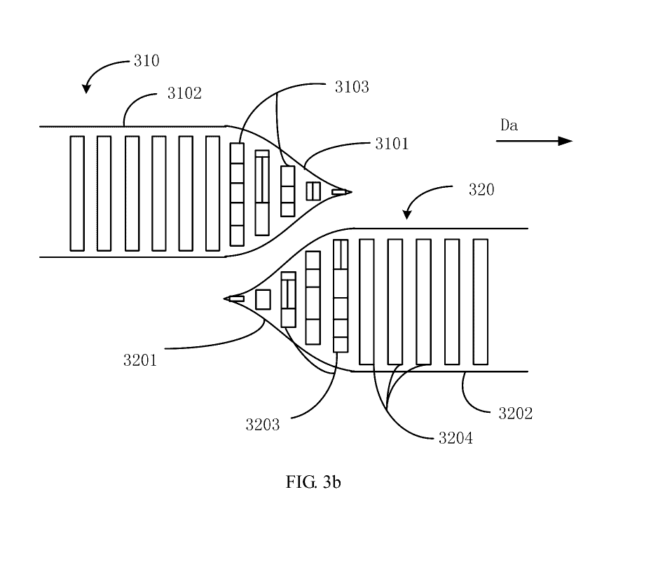

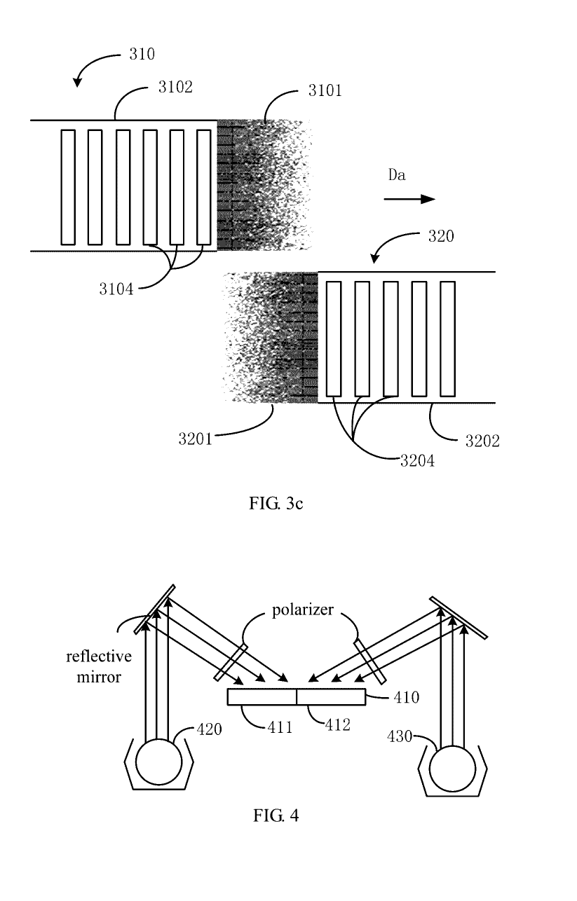

Refer to FIG. 3a for the schematic view of the second embodiment of the mask device for optical alignment according to the disclosure. The mask device 30 comprises:

a first mask 310 and a second mask 320;

the first mask 310 comprises a first overlapping region 3101 and a first non-overlapping region 3102;

the second mask 320 comprises a second overlapping region 3201 and a second non-overlapping region 3202;

the first overlapping region 3101 and the second overlapping region 3201 overlap with each other;

the first overlapping region 3101 comprises a plurality of transmission openings 3103 arranged in a first direction Da;

the first non-overlapping region 3102 comprises a plurality of transmission openings 3104 arranged in the first direction Da;

the second overlapping region 3201 comprising a plurality of transmission openings 3203 arranged in the first direction Da;

the second non-overlapping region 3201 comprises a plurality of transmission openings 3204 arranged in the first direction Da;

the openings 3104 of the first non-overlapping region 3102 and the openings 3204 of the second non-overlapping region 3202 are the same;

the height Y1 of the openings 3103 of the first overlapping region 3101 satisfies Y1=H sin²(πX/2L);

the height Y2 of the openings 3203 of the second overlapping region 3201 satisfies Y2=H cos²(πX/2L);

wherein H is the height of the openings 3104 of the first non-overlapping region 3102 and the height of the openings 3204 of the second non-overlapping region 3202; X=L−M; L is the length of the first overlapping region 3101 and the length of the second overlapping region 3201; M is the distance between the first overlapping region 3101 and the second non-overlapping region 3202 or the distance between the second overlapping region 3201 and the second non-overlapping region 3202;

the openings 3104 of the first non-overlapping region 3102 and the openings 3204 of the second non-overlapping region 3203 are a first rectangular;

the width direction of the first rectangular is the same as the first direction Da;

the openings 3103 of the first overlapping region 3101 and the openings 3203 of the second overlapping region 3201 are a plurality of third rectangular; the size of the third rectangular in the first direction Da is the same as or different from the width of the first rectangular.

It can be understood that if the first mask 310 exchanges places with the second mask 320 (ref to FIG. 3a), M is the distance between the first overlapping region 3101 and the first non-overlapping region 3102 or the distance between the second overlapping region 3201 and the first non-overlapping region 3102.

The height variation curve 32011 (not shown in FIG. 3a) of the openings 3203 of the second overlapping region 3201 and the height variation curve 31011 of the openings 3103 of the first overlapping region 3101 (not shown in FIG. 3a) satisfy to be the same as the height of the openings 3204 of the second non-overlapping region 3202 after overlapping. The specific details may refer to the related description of the first embodiment, and are not repeated herein. The openings 3103 and the openings 3203 of the plurality of the third rectangle are such configured (the size of the third rectangular at the first direction as shown in FIG. 3a being the same as the width of the openings 3104 of the non-overlapping region 3102 or the openings 3204 of the non-overlapping region 3202) that the exposure amount at the same position of the overlapping region 3101 of the first mask 310 and the overlapping region 3202 of the second mask 302 is the same as the exposure amount of the first non-overlapping region 3103 and the second non-overlapping region 3202 after overlapping.

Further, the shapes and the sizes of the plurality of the third rectangle are the same or different. In FIG. 3a, the plurality of the third rectangle having the same shapes and the sizes are taken for example.

Refer to FIG. 3b for one schematic view showing that the openings of the overlapping regions of the two masks in FIG. 3a comprise a plurality of third rectangle. As shown in FIG. 3b, at least two third rectangle of the plurality of third rectangle having different shapes and sizes are taken for example. Each opening 3103 of the first overlapping region 3101 and each opening 3203 of the second overlapping region 3201 comprise a plurality of third rectangle having different shapes and sizes such that the exposure amount passing through the openings 3103 and 3203 at the same position after the overlapping region 3101 of the first mask 310 overlap with the overlapping region 3202 of the second mask 3203 is the same as the exposure amount passing through the opening 3104 of the first non-overlapping region 3102 and the opening 3204 of the second non-overlapping region 3202.

Alternatively, the size of at least one third rectangular selected from the plurality of third rectangles at the first direction Da is different from the width of the first rectangular of the openings of the non-overlapping region.

Refer to FIG. 3c for another schematic view showing that the openings of the overlapping regions of the two masks in FIG. 3a comprise a plurality of third rectangle.

As shown in FIG. 3c, each opening 3103 of the first overlapping region 3101 and each opening 3203 of the second overlapping region 3201 comprise a plurality of third rectangle having the same shapes and sizes. And the third rectangle are sufficiently small such that the formed openings 3103 and 3203 randomly distribute at the corresponding overlapping region 3101 and 3201 to satisfy that the exposure amount passing through the openings 3103 and 3203 at the same position after the overlapping region 3101 of the first mask 310 overlap with the overlapping region 3202 of the second mask 3203 is the same as the exposure amount passing through the opening 3104 of the first non-overlapping region 3102 and the opening 3204 of the second non-overlapping region 3202.

The shape of the third rectangles may be but not limited to square.

Alternatively, the plurality of third rectangles randomly distributed is obtained by mosaic algorithm. In the specific embodiment, the shapes and sizes of the third rectangular are predetermined, and the required height Y1 and Y2 of the openings are selected. Through mosaic algorithm the openings of the overlapping region formed by the plurality of third rectangular randomly distributed are obtained.

Further, the openings 3103 of the first overlapping region 3101 of the first mask 310 and the openings 3203 of the second overlapping region 3201 are arranged symmetrically or asymmetrically. The specific details may refer to the related description of the first embodiment, and are not repeated herein.

Further, alternatively, the openings 3103 of the first overlapping region 3101 of the first mask 310 and the openings 3203 of the second overlapping region 3201 may overlap or do not overlap with each other.

Distinguishing from the current technology and the first embodiment mentioned above, the embodiment configures the openings in the overlapping regions of the two masks as the third rectangular, such as mosaic arrangement. The height variation of the openings of the overlapping region satisfies the curve variation of the trigonometric square such that the exposure amount of the openings changes smoother. In the overlapping regions, it satisfies H sin²(πX/2L)+H cos²(πX/2L)=H at the same position. That is the exposure amount of the openings of the overlapping regions and the exposure amount of the openings of the non-overlapping regions is the same after the two masks overlap with each other such that the display effects are uniform in the liquid crystal display device. In the meanwhile, the openings of curved variation may eliminate the defects of the stripped mura in the liquid crystal display device to increase the display quality of the products.

Refer to FIG. 4 for the schematic view of the third embodiment of the exposure equipment for optical alignment according to the disclosure.

The exposure equipment comprises the mask device 410 as the first or the second embodiment mentioned above, a first light source 420 and a second light source 430.

The first light source 420 provides light for the openings of the first mask 411.

The second light source 430 provides light for the openings of the second mask 412.

The configuration of the first light source 420 and the second light source 430 is the same as the current configuration of the existing exposure equipment. The light source may be configured at the side surfaces of the exposure equipment and may be irradiated onto the first mask 411 and the second mask 412 under different angles by a plurality of reflective mirrors and polarizers.

In other embodiment, only one light source may be selected. The light may be irradiated onto the first mask 410 and the second mask 420 under different angles by a plurality of reflective mirrors and beam splitters. Those are the same as the current technology and are not repeated herein.

The first light source and the second light source are ultraviolet lights, which are the current technology and are not repeated herein.

Distinguishing from the current technology, the first or the second embodiment as mentioned above, the embodiment configures the openings in the overlapping regions of the two masks to satisfy the curve variation of the trigonometric square such that the exposure amount of the openings changes more smoother. In the overlapping regions, it satisfies H sin²(πX/2L)+H cos²(πX/2L)=H at the same position. That is the exposure amount of the openings of the overlapping regions and the exposure amount of the openings of the non-overlapping regions is the same after the two masks overlap with each other such that the display effects are uniform in the liquid crystal display device. In the meanwhile, the openings of curved variation may eliminate the defects of the stripped mura in the liquid crystal display device to increase the display quality of the products.

Note that the specifications relating to the above embodiments should be construed as exemplary rather than as limitative of the present disclosure. The equivalent variations and modifications on the structures or the process by reference to the specification and the drawings of the disclosure, or application to the other relevant technology fields directly or indirectly should be construed similarly as falling within the protection scope of the disclosure.

What is claimed is:

1. An optical mask device for optical alignment comprising:
a first mask and a second mask;
the first mask comprises a first overlapping region and a first non-overlapping region;
the second mask comprises a second overlapping region and a second non-overlapping region;
the first overlapping region and the second overlapping region overlap with each other;
the first overlapping region comprises a plurality of transmission openings arranged in a first direction;
the first non-overlapping region comprises a plurality of transmission openings arranged in the first direction;
the second overlapping region comprising a plurality of transmission openings arranged in the first direction;
the second non-overlapping region comprises a plurality of transmission openings arranged in the first direction;
the openings of the first non-overlapping region and the openings of the second non-overlapping region are the same;
the height Y1 of the openings of the first overlapping region satisfies Y1=H sin²(πX/2L);
the height Y2 of the openings of the second overlapping region satisfies Y2=H cos²(πX/2L);
wherein H is the height of the openings of the first non-overlapping region and the height of the openings of the second non-overlapping region; X=L−M; L is the length of the first overlapping region and the length of the second overlapping region; M is the distance between the first overlapping region and the second non-overlapping region or the distance between the second overlapping region and the second non-overlapping region;
the openings of the first non-overlapping region and the openings of the second non-overlapping region are a first rectangular;
the width direction of the first rectangular is the same as the first direction;
the openings of the first overlapping region and the openings of the second overlapping region are a plurality of third rectangular; the size of the third rectangle in the first direction is the same as or different from the width of the first rectangular;
the openings of the first overlapping region and the openings of the second overlapping region are arranged symmetrically or asymmetrically.

2. The device according to claim 1, wherein the openings of the first overlapping region and the openings of the second overlapping region are obtained by mosaic algorithm.

3. An optical mask device for optical alignment comprising:
a first mask and a second mask;
the first mask comprises a first overlapping region and a first non-overlapping region;
the second mask comprises a second overlapping region and a second non-overlapping region;
the first overlapping region and the second overlapping region overlap with each other;
the first overlapping region comprises a plurality of transmission openings arranged in a first direction;
the first non-overlapping region comprises a plurality of transmission openings arranged in the first direction;
the second overlapping region comprising a plurality of transmission openings arranged in the first direction;
the second non-overlapping region comprises a plurality of transmission openings arranged in the first direction;
the openings of the first non-overlapping region and the openings of the second non-overlapping region are the same;
the height Y1 of the openings of the first overlapping region satisfies Y1=H sin²(πX/2L);
the height Y2 of the openings of the second overlapping region satisfies Y2=H cos²(πX/2L);
wherein H is the height of the openings of the first non-overlapping region and the height of the openings of the second non-overlapping region; X=L−M; L is the length of the first overlapping region and the length of the second overlapping region; M is the distance between the first overlapping region and the second non-overlapping region or the distance between the second overlapping region and the second non-overlapping region.

4. The device according to claim 3, wherein:
the openings of the first non-overlapping region and the openings of the second non-overlapping are being a first rectangular;
the width direction of the first rectangular is the same as the first direction;
the openings of the first overlapping region and the openings of the second overlapping region are a second rectangle; the size of the second rectangular in the first direction is the same as the width of the first rectangular.

5. The device according to claim 3, wherein:
the openings of the first non-overlapping region and the openings of the second non-overlapping region are a first rectangular;
the width direction of the first rectangular is the same as the first direction;
the openings of the first overlapping region and the openings of the second overlapping region are a plurality of third rectangular; the size of the third rectangular in the first direction is the same as or different from the width of the first rectangular.

6. The device according to claim 5, wherein the openings of the first overlapping region and the openings of the second overlapping region are obtained by mosaic algorithm.

7. The device according to claim 3, wherein the openings of the first overlapping region and the openings of the second overlapping region overlap with each other.

8. The device according to claim 3, wherein the openings of the first overlapping region and the openings of the second overlapping region do not overlap with each other.

9. The device according to claim 3, wherein the openings of the first overlapping region and the openings of the second overlapping region are arranged symmetrically or asymmetrically.

10. An exposure equipment comprising a mask device, a first light source and a second light source, wherein the mask device comprises:
a first mask and a second mask;
the first mask comprises a first overlapping region and a first non-overlapping region;
the second mask comprises a second overlapping region and a second non-overlapping region;
the first overlapping region and the second overlapping region overlap with each other;
the first overlapping region comprises a plurality of transmission openings arranged in a first direction;
the first non-overlapping region comprises a plurality of transmission openings arranged in the first direction;
the second overlapping region comprising a plurality of transmission openings arranged in the first direction;
the second non-overlapping region comprises a plurality of transmission openings arranged in the first direction;
the openings of the first non-overlapping region and the openings of the second non-overlapping region are the same;
the height Y1 of the openings of the first overlapping region satisfies Y1=H sin²(πX/2L);
the height Y2 of the openings of the second overlapping region satisfies Y2=H cos²(πX/2L);
wherein H is the height of the openings of the first non-overlapping region and the height of the openings of the second non-overlapping region; X=L−M; L is the length of the first overlapping region and the length of the second overlapping region; M is the distance between the first overlapping region and the second non-overlapping region or the distance between the second overlapping region and the second non-overlapping region;
the first light source provides light for the openings of the first mask;
the second light source provides light for the openings of the second mask.

11. The equipment according to claim 10, wherein:
the openings of the first non-overlapping region and the openings of the second non-overlapping region are a first rectangular;
the width direction of the first rectangular is the same as the first direction;
the openings of the first overlapping region and the openings of the second overlapping region are a second rectangle; the size of the second rectangular in the first direction being the same as the width of the first rectangular.

12. The equipment according to claim 10, wherein:
the openings of the first non-overlapping region and the openings of the second non-overlapping region are a first rectangular;
the width direction of the first rectangular is the same as the first direction;
the openings of the first overlapping region and the openings of the second overlapping region are a plurality of third rectangular; the size of the third rectangular in the first direction is the same as or different from the width of the first rectangular.

13. The equipment according to claim 12, wherein the openings of the first overlapping region and the openings of the second overlapping region are obtained by mosaic algorithm.

14. The equipment according to claim 10, wherein the openings of the first overlapping region and the openings of the second overlap region overlap with each other.

15. The equipment according to claim 10, wherein the openings of the first overlapping region and the openings of the second overlapping region do not overlap with each other.

16. The equipment according to claim 10, wherein the openings of the first overlapping region and the openings of the second overlapping region are arranged symmetrically or asymmetrically.

17. The equipment according to claim 10, wherein the first light source and the second light source are ultraviolet lights.
